(19) United States
(12) Patent Application Publication
(10) Pub. No.: US 2026/0082514 A1
(43) Pub. Date: Mar. 19, 2026

(54) HEAT DISSIPATION DEVICE, MANUFACTURING METHOD OF HEAT DISSIPATION DEVICE AND ELECTRONIC EQUIPMENT

(71) Applicants: CHAMP TECH OPTICAL (FOSHAN) CORPORATION, Foshan (CN); HON HAI PRECISION INDUSTRY CO., LTD., New Taipei (TW)

(72) Inventors: Pei-Jen Lin, New Taipei (TW); Fu-Lin Yang, New Taipei (TW); Wen-Hsien Lin, New Taipei (TW)

(21) Appl. No.: 19/021,743

(22) Filed: Jan. 15, 2025

(30) Foreign Application Priority Data
Sep. 18, 2024 (CN) 202411304511.2

(51) Int. Cl. H05K 7/20; F28D 21/00

(52) U.S. Cl. CPC H05K 7/20336; H05K 7/20327; H05K 7/20436; F28D 2021/0019; F28F 2255/00

(57) ABSTRACT

A heating dissipation device, comprising a medium transmission member, a plurality of heat exchange units and a plurality of heat exchange members. The medium transmission member comprising a transmission cavity for conveying a heat exchange medium. The plurality of heat exchange units are spaced apart from each other and connected to the medium transmission member, two adjacent heat exchange units are defined a receiving space therebetween, the receiving space receives a corresponding heat source member therein, the heat exchange units has a heat exchange cavity. Each of the plurality of heat exchange members is respectively arranged in a corresponding each of the plurality of heat exchange cavities, the heat exchange unit absorbs heat generated from the heat source member, then the heat is transferred to the transmission member via the heat exchange member. Each of the plurality of heat exchange units has a first state and a second state.

### FIELD

The present disclosure relates to the technical field of heat dissipation, in particular to a heat dissipation device and an electronic equipment.

### BACKGROUND

During operation of a computer device, memory module, central processing unit (CPU), and Graphics Processing Unit (GPU) consume most of power consumption of a computer and are important objects for heat dissipation. In some known technologies, air cooling is mainly used to dissipate heat from the memory module, but heat dissipation efficiency of air cooling is low.

### BRIEF DESCRIPTION OF THE DRAWINGS

In order to illustrate the technical solutions of the embodiments of the present application more clearly, the accompanying drawings in the embodiments will be briefly introduced below. It should be understood that the following drawings only show some embodiments of the present application, and therefore should not be seen as the limiting the scope. For one of ordinary skill in the art, other related drawings can also be obtained from these drawings without any creative work.

Implementations of the present technology will now be described, by way of embodiments, with reference to the attached figures, wherein:

FIG. 1 shows a schematic structural view of an electronic equipment in an embodiment of the present disclosure.

FIG. 2 shows a sectioned view of a heat dissipation device in an embodiment of the present disclosure.

FIG. 3 shows a sectioned view of a heat dissipation device and a heat source member in an embodiment of the present disclosure, a heat exchange unit of the heat dissipation device is in a first state.

FIG. 4 shows a sectioned view of the heat dissipation device and the heat source member shown in FIG. 3, the heat exchange unit of the heat dissipation device is in a second state.

FIG. 5 shows a sectioned view of a heat dissipation device and a heat source member in the electronic equipment shown in FIG. 1.

FIG. 6 shows a sectioned view of a connection area of a heat exchange member, a heat exchange unit and a medium transmission member in an embodiment of the present disclosure.

FIG. 7 shows a schematic diagram of a heat exchange unit and a card connector in an embodiment of the present disclosure.

FIG. 8 shows an explosive view of a heat exchange unit and a card connector in an embodiment of the present disclosure.

FIG. 9 shows a sectioned view of a heat dissipation device and a heat source member in another embodiment of the present disclosure, a heat exchange unit of the heat dissipation device is in a second state.

FIG. 10 shows a sectioned view of a heat exchange unit in another embodiment of the present disclosure.

FIG. 11 shows a perspective view of a heat dissipation device in another embodiment of the present disclosure.

FIG. 12 shows a sectioned view of a heat exchange unit, a first medium transmission member and a second medium transmission member of the heat dissipation device in FIG. 11.

FIG. 13 shows a sectioned view of a connection area of a heat exchange member, a heat exchange unit and a medium transmission member in another embodiment of the present disclosure.

FIG. 14 shows a sectioned view of a connection area of a heat exchange member, a heat exchange unit and a medium transmission member in another embodiment of the present disclosure.

FIG. 15 shows a sectioned view of the heating dissipation device in manufacturing process.

FIG. 16 shows another sectioned view of the heating dissipation device in manufacturing process.

FIG. 17 shows another sectioned view of the heating dissipation device in manufacturing process.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale, and the proportions of certain parts may be exaggerated to illustrate details and features better. The description is not to be considered as limiting the scope of the embodiments described herein.

Several definitions that apply throughout this disclosure will now be presented.

The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

The technical solutions in the embodiments of the present application will be clearly and completely described below with reference to the accompanying drawings in the embodiments of the present application. Obviously, the described embodiments are only a part of the embodiments of the present application, but not all of the embodiments.

It should be noted that when an element is referred to as being “fixed to” another element, it can be directly on the other element or intervening elements may also be present. When an element is referred to as being “connected” to another element, it can be directly connected to the other element or intervening elements may also be present. When an element is referred to as being “disposed on” another element, it can be directly disposed on the other element or intervening elements may also be present. The terms “vertical” “horizontal” “left” “right” and similar expressions are used herein for illustrative purposes only.

Unless otherwise defined, all technical and scientific terms used herein have the same meaning as commonly understood by one of ordinary skill in the art. The terms used herein in the specification of the present application are for the purpose of describing particular embodiments only, and are not intended to limit the present application. As used herein, the term “or/and” includes any and all combinations of one or more of the associated listed items.

Some embodiments of the present application are described in detail. The following embodiments and features of the embodiments may be combined with each other without conflict.

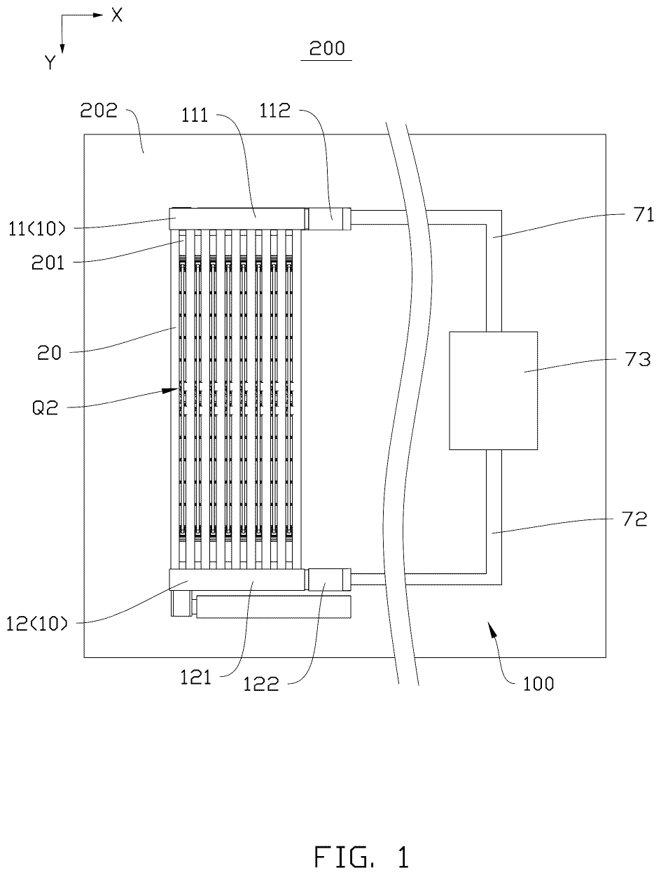

Referring to FIG. 1, an embodiment of the present disclosure provides an electronic equipment 200. The electronic equipment 200 may be a computer, a server, a switch, a base station or other types of network equipment or computer equipment. The electronic equipment 200 includes a heat source member 201, a circuit board 202 and a heating dissipation device 100. The heat source member 201 detachably connects to the circuit board 202. The heat source member 201 may be any component that is capable of heating during operation and requiring heat dissipation treatment. For example, the heat source member 201 may be any electrical component such as a CPU, power supply chip, processor chip, control chip, various functional chips, circuits, memory strips (memory particles) or graphics card. The heat dissipation device 100 is arranged on the circuit board 202 to absorb heat from the heat source member 201.

In one embodiment, the heat source member 201 is a memory module, the circuit board 202 is a mainboard. The memory module 201 may be a Single In-line Memory module 201 (DIMM) or a Dual-Inline-Memory-Module (DIMM) .

In one embodiment, a first direction X is a width direction of the memory module 201, a second direction Y is a length direction Y of the memory module 201, a third direction Z is a height direction of the memory module 201, and direction of gravity is parallel to the third direction Z.

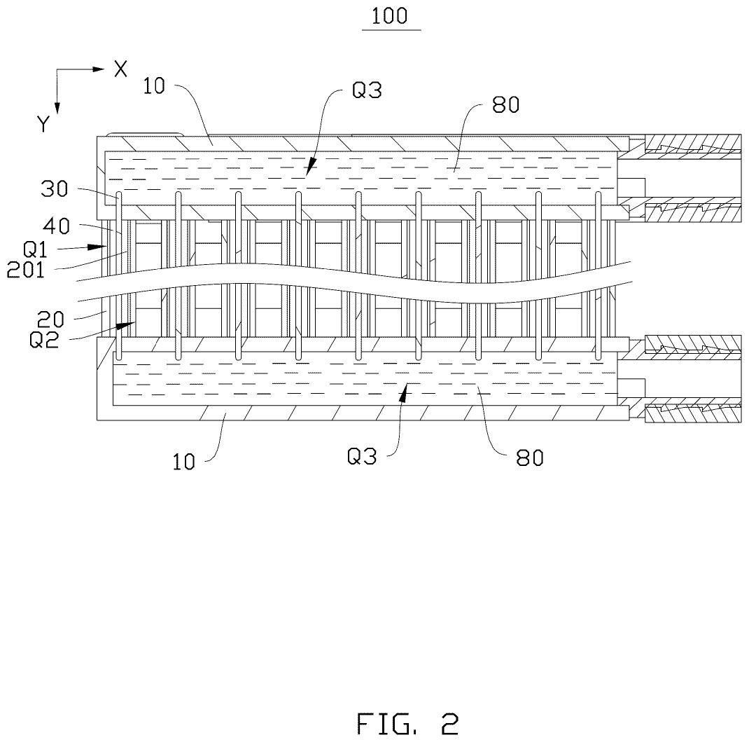

Referring to FIG. 2, in one embodiment, the heating dissipation device 100 includes at least one medium transmission member 10, a plurality of heat exchange units 20 and a plurality of heat exchange members 30. The medium transmission member 10 includes a transmission cavity Q1 configured for conveying a heat exchange medium 80. The plurality of heat exchange units 20 spaced apart from each other and connected to the medium transmission member 10. A receiving space Q2 is defined between each two adjacent heat exchange units 20. The receiving space Q2 receives a heat source member 201. Each of the plurality of heat exchange units 20 has a heat exchange cavity Q1. Each of the plurality of heat exchange members 30 is respectively arranged in a corresponding each of the plurality of heat exchange cavities Q1. The heat exchange member 30 is configured to absorb heat generated from the heat source member 201, and transfer the heat to the transmission member 10. The heat exchange unit 20 absorbs heat generated from the heat source member 201, then the heat is transferred to the transmission member 10 via the heat exchange member 30. Each of the plurality of heat exchange units 20 is configured to be in a first state or in a second state. When a heat exchange unit 20 of the plurality of heat exchange units 20 is in the first state, adjacent heat exchange units 20 of the plurality of heat exchange units 20 are spaced apart from the heat source member 201, and a size of the receiving space Q2 is slightly larger than a size of the heat source member 201. When the heat exchange unit 20 is in the second state, the heat exchange unit 20 is expanded, and the adjacent heat exchange units 20 are close to each other to clamp the heat source member 201. In this state, the size of the receiving space Q2 is slightly less than the size of the heat source member 201.

According to the heat dissipation device 100 of this embodiment, when the heat exchange unit 20 is in the first state, the heat source member 201 can be conveniently putted into the receiving space Q2 without damaging the heat exchange unit 20. That a heat exchange effect of the heat exchange unit 20 is ensured. After changed the state of the heat exchange unit 20 to the second state, the heat source member 201 is clamped by the exchange units 20 tightly. In this state, the heat exchange unit 20 absorbs heat generated from the heat source member 201, then the heat is transferred to the transmission member 10 via the heat exchange member 30.

In one embodiment, the heat exchange medium 80 may be a coolant, the coolant may be water (deionized water), mineral oil, silicone oil, synthetic ester oil, fluorinated oil or fluorinated liquid, etc.

In one embodiment, number of the memory module 201s is multiple, and the multiple memory module 201s are arranged at intervals in the first direction X. in another embodiment, one receiving space Q2 can receive a plurality of memory module 201s, the plurality of memory module 201s in one receiving space Q2 is spaced from each other along the second direction Y.

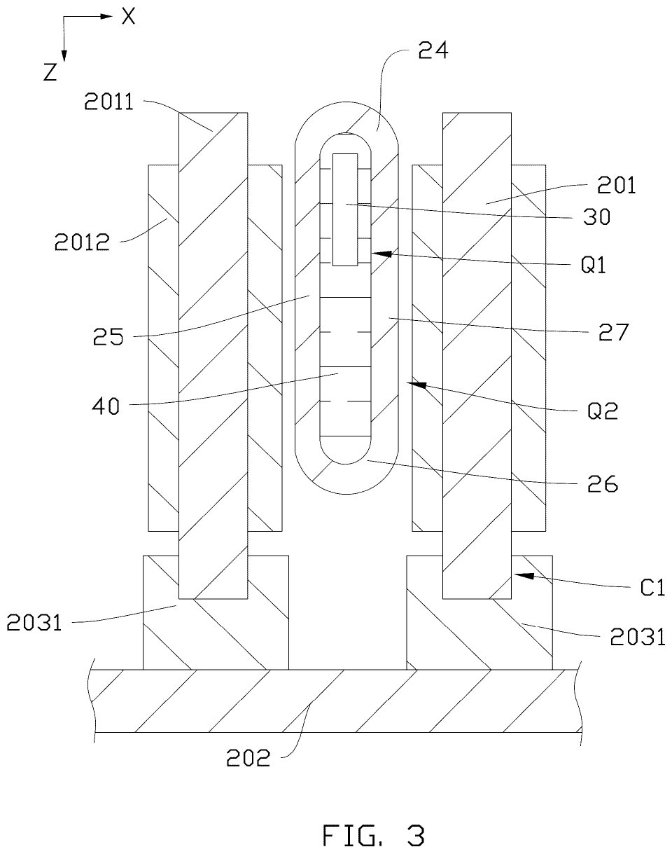

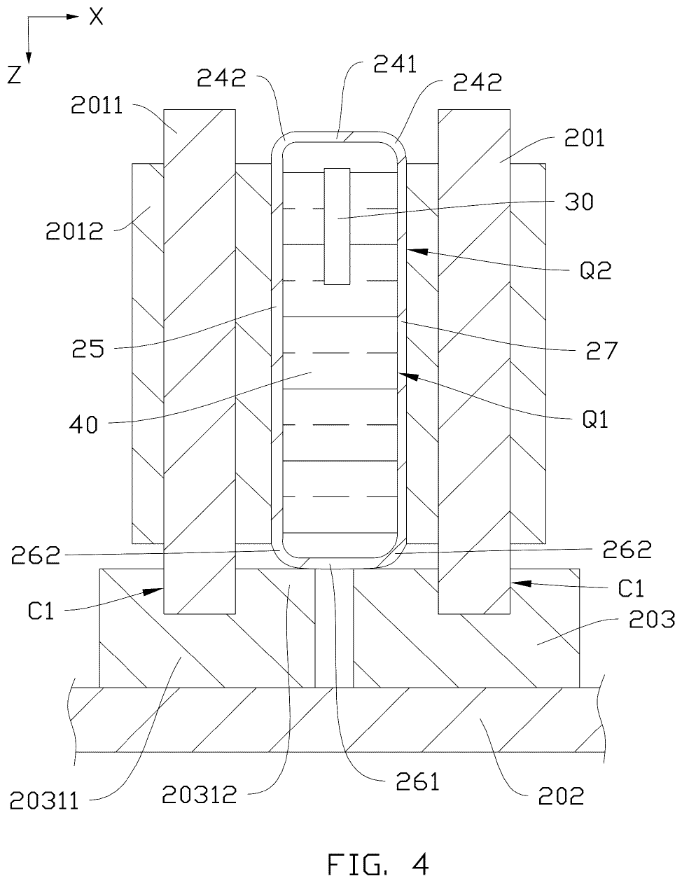

In one embodiment, referring to FIG. 3 and FIG. 4, the heat exchange unit 20 includes a top wall 24, a first side wall 25, a bottom wall 26 opposite to the top wall 24, and a second side wall 27 opposite to the first second wall 24. The top wall 24 and the bottom wall 26 are spaced apart along the third direction Z, and the first side wall 25 and the second side wall 27 are spaced apart along the first direction X. The top wall 24, the first side wall 25, the bottom wall 26, and the second side wall 27 are connected sequentially along a periphery direction of the heat exchange unit 20 to define the heat exchange cavity Q1 therebetween. When the heat exchange unit 20 is in the second state, the first side wall 25 resisted one side of one memory module 201, and the second side wall 27 resisted another side of the adjacent memory module 201, and the heat exchange unit 20 can absorb heat of the two adjacent memory module 201s.

Each of the plurality of heat exchange units 20 is configured to accommodate a phase change medium 40 between the heat exchange member 30 and an inner surface of a corresponding heat exchange unit 20 of the plurality of heat exchange units 20. The corresponding heat exchange unit 20 is further configured to be in the first state when a temperature of the phase change medium 40 is below a preset value, and the phase change medium 40 is solid. The corresponding heat exchange unit 20 is further configured to switch to the second state when the temperature of the phase change medium 40 is equal to or above the preset value, and the phase change medium 40 is changed to gas, liquid or a mixture mixed with gas and liquid. And the corresponding heat exchange unit 20 is expanded by expanding the first side wall 25 and the second side wall 27 by a distance by the phase change medium 40, such that at least one of the first side wall and the second side wall clamps the heat source member, thereby forming a heat transfer path from the heat source member 201 to the corresponding heat exchange unit 20, to the phase change medium 40, to the heat exchange member 30, and to the heat exchange medium 80.

The phase change medium 40 is changed to gas, liquid or a mixture mixed with gas and liquid when its temperature is equal to or above the preset value. An inner space of the heat exchange unit 20 is expanded by the gas, the liquid or the mixture, and the heat exchange unit 20 is switched to the second state. The heat exchange unit 20 absorbs heat generated from the heat source member 201, then the heat is transferred to the phase change medium 40 to make the phase change medium 40 phase changed, and a part of the heat absorbed by the phase change medium 40 is transferred to the heat exchange member 30, simultaneously, and then the heat absorbed by the exchange member 30 is transferred to the heat exchange medium 80 filled in the medium transmission member 10. The heat of the heat exchange medium 80 is transferred to external environment or other heat-absorbing equipment.

Referring to FIGS. 3 and 4, when the heat exchange unit 20 is in the first state, a first distance is defined between the first side wall 25 and the second side wall 27 along the first direction X. When the heat exchange unit 20 is in the second state, a second distance is defined between the first side wall 25 and the second side wall 27 along the first direction X. The first distance is smaller than the second distance, and the first distance is smaller than a space between two adjacent heat exchange unit 20 in the first direction X, and the adjacent heat exchange units 20 are closed to each other two to clamp the corresponding heat source member 201 therebetween. During manufacturing process of the heat dissipation device 100, a temperature of the phase change medium 40 above the preset value is increased, and the phase change medium 40 is changed to the gas, the liquid or the mixture, and a shape of the heat exchange unit 20 is changed to the first state. The phase change medium 40 is cooled to the solid, and the heat source member 201 is received in the two adjacent heat exchange unit 20.

When the electronic equipment 200 is worked, the temperature of the heat source member 201 is increased, and the heat exchange unit 20 absorbs heat generated from the heat source member 201 via air. The temperature of the phase change medium 40 is increased to greater than or equal to the preset value, and the phase change medium 40 is changed to the gas, the liquid or the mixture. The phase change medium 40 resisted the bottom wall 26, the first side wall 25 and the second side wall 27 of the heat exchange unit 20 via gravity. The distance between the first side wall 25 and the second side wall 27 is increased, until the first side wall 25 and the second side wall 27 respectively resisted the two adjacent heat source member 201 in two sides of the heat exchange unit 20. When the heat source member 201 is memory module 201, the first side wall 25 and the second side wall 27 resisted the chip 2012 of the memory module 201. Therefore, the medium transmission member 10 and the heat exchange medium 80 can absorb heat via the heat exchange member 30, the phase change medium 40, the heat exchange unit 20 and the heat source member 20.

Furthermore, when the bottom wall 26 is resisted via the phase change medium 40, the bottom wall 26 moved closer to the circuit board 202 in the third direction Z. The first side wall 25 and the second side wall 27 are stretched via the bottom wall 26, and the first side wall 25 and the second side wall 27 extended to the circuit board 202 in the third direction Z. A contact area is increased between the heat exchange unit 20 and the heat source member 201 in the third direction Z, and this increasing a heat dissipation effect of the memory module 201 with different dimensions of chips 2012 in the third direction Z.

In one embodiment, referring again to FIGS. 3 and 4, when the heat exchange unit 20 is in the first state, the top wall 24 is curved outward in the third direction Z, and the bottom wall 26 is curved outward in the third direction Z. When the heat exchange unit 20 is in the second state, the top wall 24 includes a first straight section 241 and two first arc sections 242. A first arc section 242 connects to one end of the first straight section 241 and the first side wall 25, and another first arc section 242 connects to the other end of the first straight section 241 and the second side wall 27. The bottom wall 26 includes a second straight section 261 and two second arc sections 262. A second arc section 262 connects to one end of the second straight section 261 and the first side wall 25, and the other second arc section 262 connects to the other end of the second straight section 261 and the second side wall 27. When the heat exchange unit 20 is switched from the first state to the second state, the first side wall 25 and the second side wall 27 to extend in the third direction Z via the phase change medium 40. The contact area between the first side wall 25 and the heat source member 201 is increased, the contact area between the second side wall 27 and the heat source member 201 is increased. The first arc section 242 can improve a connection reliability between the first straight section 241 and the first side wall 25 or the second side wall 27. The second arc section 262 can improve a connection reliability between the second straight section 261 and the first side wall 25 or the second side wall 27.

In one embodiment, the roof wall 24, the first side wall 25, the bottom wall 26 and the second side wall 27 are integrally formed to constitute the heat exchange unit 20, improving a permeability resistance of the heat exchange unit 20.

In one embodiment, the phase change medium 40 may be industrial wax, such as paraffin wax, microcrystalline wax. The industrial wax has excellent insulation and thermal property, a safety of heat dissipation device 100 is enhanced and a heat exchange efficiency is ensured in the electronic equipment 200. Furthermore, the industrial wax has a low melting point, this allowing the preset value to be set within a lower range, and the industrial wax can facilitate rapid liquefaction for efficient heat exchange with the heat source member 201. In other embodiments, the phase change medium 40 may be constructed from other metals with low melting points, such as bismuth-lead alloys.

In one embodiment, the preset value is greater than or equal to 35° C., and the preset value is less than or equal to 45° C. For example, the preset value is any one of 35° C., 36° C., 37° C., 38° C., 39° C., 40° C., 41° C., 42° C., 43° C., 44° C., or 45° C.

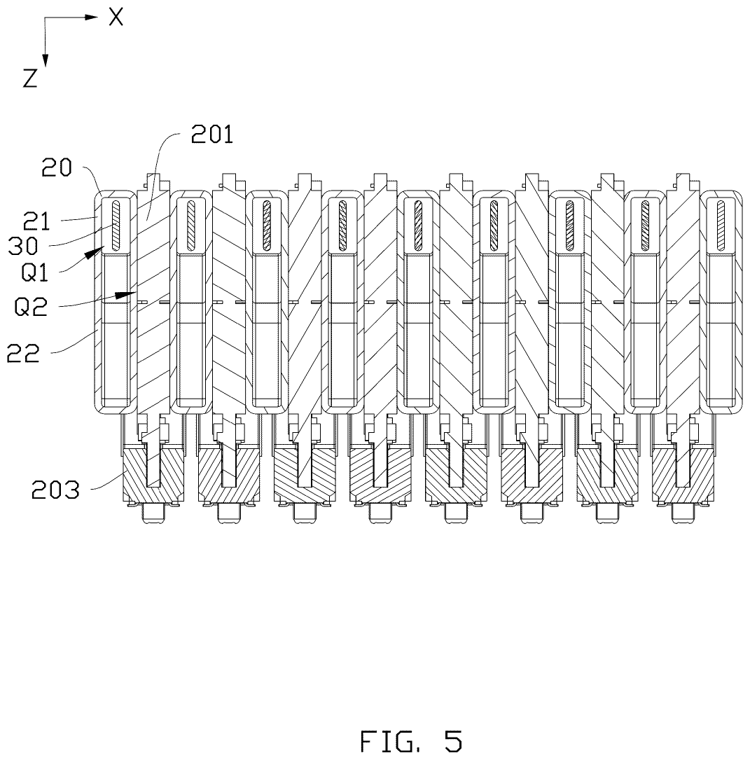

In one embodiment, referring to FIG. 5, when the heat exchange unit 20 is in the second state, the heat exchange member 30 is spaced apart from an inner surface of the heat exchange unit 20, and a probability of collision between the heat exchange member 30 and the heat exchange unit 20 is reduced, and a service life of the heat dissipation device 100 is improved.

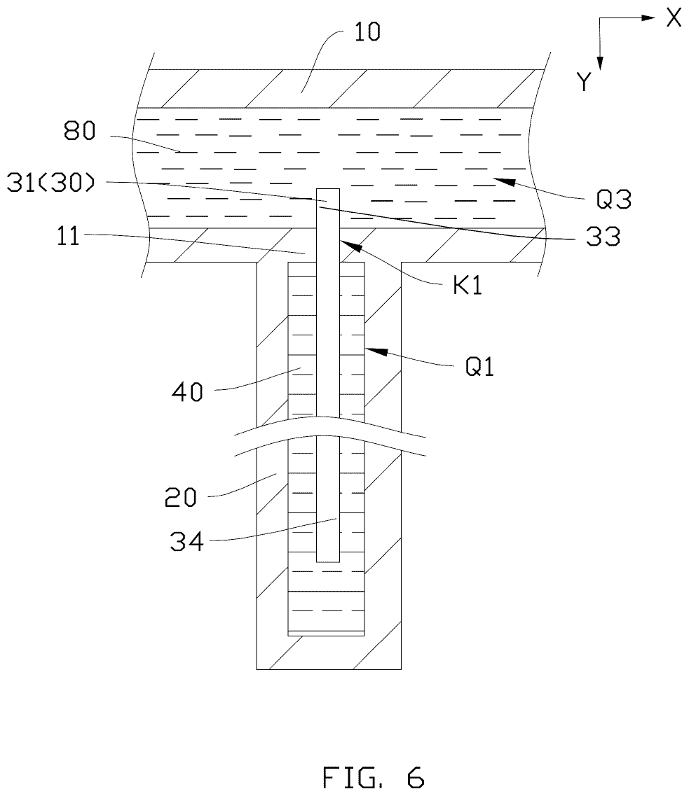

In one embodiment, referring to FIG. 6, the heat exchange member 30 has a first end 33 and a second end 34. The first end 33 and the second end 34 are spaced apart in the second direction Y.

In one embodiment, referring to FIG. 6, the medium transmission member 10 has a connection side wall 13, the connection side wall 13 has a communication hole K1. The communication hole K1 is communicated with the transmission cavity Q3. A end of the heat exchange member 30 is extended into the communication hole K1, and the heat exchange member 30 is connected to the medium transmission member 10. The heat exchange medium 80 absorbs heat from the heat exchange member 30, and a heat exchange efficiency between the heat exchange member 30 and the heat exchange medium 80 is improved.

In one embodiment, referring to FIG. 6, the first end 33 is passed through the communication hole K1 and extended into the transmission cavity Q3 to increase the contact area between the heat exchange member 30 and the heat exchange medium 80, and improve heat exchange efficiency between the heat exchange member 30 and the heat exchange medium 80.

In one embodiment, referring to FIG. 6, the heat exchange member 30 is sealed connected with the medium transmission member 10, the heat exchange cavity Q1 is isolated from the transmission cavity Q3. The heat exchange member 30 and the medium transmission member 10 may be sealed connected by welding, such as brazing. The heat exchange member 30 is a heat conductive sheet 31 made of a heat conductive material. This preventing the heat exchange medium 80 in the medium transmission member 10 from entering the heat exchange unit 20, and a risk of leakage of the heat exchange medium 80 is reduced and a stable conveyance of the heat exchange medium 80 in the medium transmission member 10 is ensured.

In another embodiment, the heat exchange cavity Q1 is communicated with the transmission cavity Q3. Before the heat source member 201 is installed or removed, the heat exchange medium 80 is drained from the heat exchange cavity Q1, and the heat exchange unit 20 is switched in the first state. After the heat source member 201 is inputted, the heat exchange medium 80 is imported into the heat exchange cavity Q1 from the transmission cavity Q3, the heat exchange unit 20 is switched to the second state and is contacted with the heat source member 201. A heat exchange efficiency between the heat exchange medium 80 and the heat source member 201 is improved via the heat exchange member 30, thereby improving cooling efficiency of the heat source member 201.

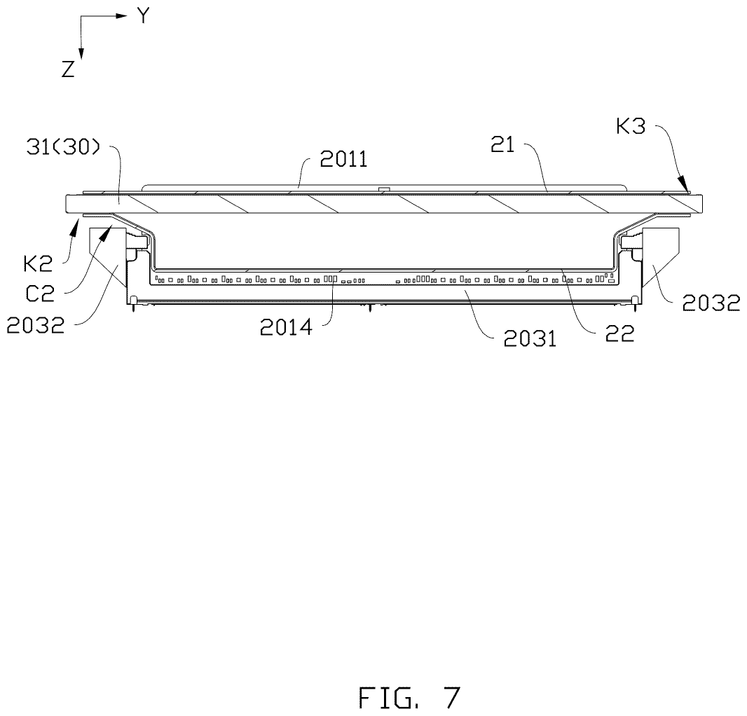

In one embodiment, referring to FIG. 7, the heat exchange unit 20 includes a first heat exchange section 21 and a second heat exchange section 22. The first heat exchange section 21 is connected to the medium transmission member 10, and the heat exchange member 30 is received in the first heat exchange section 21 of the corresponding heat exchange unit 20, and a gap is defined between the heat exchange member 30 and an inner surface of the first heat exchange section 21 of the corresponding heat exchange unit 20. The second heat exchange section 22 is connected to a downside in a gravity direction of the first heat exchange section 21 the corresponding heat exchange unit 20. When the phase change medium 40 is transformed to the gas, the liquid or the mixture, the second heat exchange section 22 and the first heat exchange section 21 is pulled via the phase change medium 40 downward under the gravity. The top wall 24 is contacted to the heat exchange member 30. A part of the phase change medium 40 is filled between the heat exchange member 30 and the top wall 24. A possibility of contact between the heat exchanger member 30 and the heat exchanger unit 20 is reduced, and a protection of the heat exchange unit 20 is improved, and a possibility of leakage of the phase change medium 40 is improved, and a service life and safety of the heat dissipation device 100 is improved.

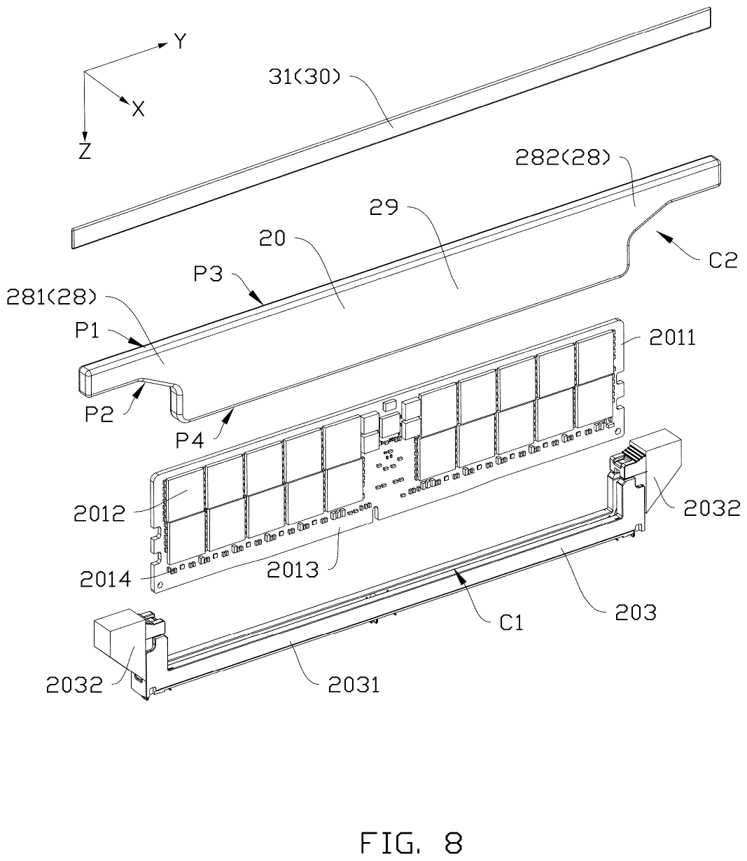

In one embodiment, referring to FIG. 8, the first heat exchange section 21 includes a connection part 28 and a main part 29. The connection part 28 is connected to one end of the main part 29 in the second direction Y. A height of the connection part 28 in the third direction Z is gradually increased towards the main part 29. And a height of the connection part 28 is smaller than a height of the main part 29. A slot C2 is defined between the connection part 28 and the main part 29. The slot C2 can receive other components of the heat dissipation device 100, and an installation applicability of the heat dissipation device 100 is improved.

In one embodiment, referring to FIG. 8, the heat exchange unit 20 includes a first connection part 281 and a second connection part 282. The first connection part 281 is connected to one end of the main part 29 and the first medium transmission member 11. The second connection part 282 is connected to another end of the main part 29 and the second medium transmission member 12.

In one embodiment, referring to FIG. 7 and FIG. 8, the electronic equipment 200 further includes a card connector 203. The card connector 203 is arranged on the mainboard. The golden finger 2013 of the memory module 201 is plugged in the card connector 203.

In one embodiment, referring to FIG. 7 and FIG. 8, the card connector 203 includes an insertion portion 2031 and two locking portions 2032. The two locking parts 2032 are respectively connected to two opposite sides of the insertion portion 2031 in the second direction Y. The memory module 201 includes a base plate 2011 and a plurality of chips 2012. The plurality of chips 2012 are mounted on two opposite sides of the base plate 2011. The golden finger 2013 is arranged on a bottom of the base plate 2011. An insertion groove C1 is defined on the insertion portion 2031 has an insertion groove C1. The golden finger 2013 is inserted in the insertion groove C1. The locking part 2032 is connected to the base plate 2011, and the memory module 201 is stably inserted into the card connector 203, and a reliability of connection between the memory module 201 and the mainboard is ensured.

In one embodiment, referring to FIG. 8, the connection part 28 has a delivery top wall P1 and a delivery bottom wall P2. The delivery top wall P1 and a delivery bottom wall P2 are spaced apart in the third direction Z. The main part 29 has a heat exchange top wall P3 and a heat exchange bottom wall P4. The delivery top wall P1 is connected to and parallel with the heat exchange top wall P3. The delivery bottom wall P2 is located between the heat exchange top wall P3 and the heat exchange bottom wall P4 in the third direction Z. A distance between the delivery bottom wall P2 and the delivery top wall P1 is gradually increased towards the main part 29 in the second direction Y. The slot C2 is defined on the delivery bottom wall P2, and the locking part 2032 is received in the slot C2.

In one embodiment, referring to FIG. 8, the main part 29 corresponds to the insertion portion 2031 in the third direction Z. The first connection part 281 and the second connection part 282 are respectively corresponded to the two locking parts 2032 in the third direction Z. The first connection part 281 and the second connection part 282 are respectively located above the two locking parts 2032 the third direction Z. When the heat exchange unit 20 is in the first state, the connection part 28 is spaced apart from the locking part 2032, thereby ensuring an installation reliability of the heat dissipation device 100.

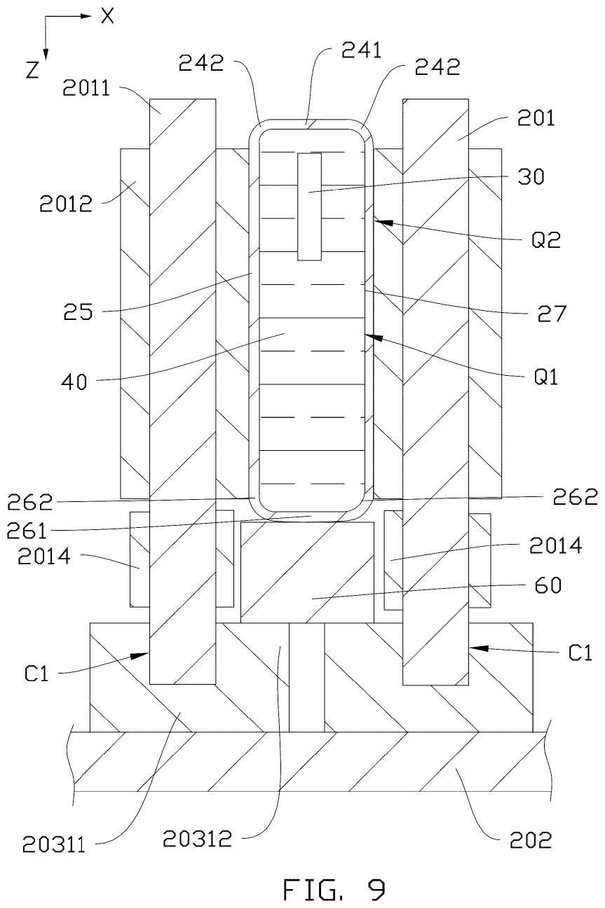

In one embodiment, referring to FIG. 9, the insertion portion 2031 includes an insertion bottom wall 20311 and two insertion side walls 20312. The two insertion side walls 20312 are respectively connected to two opposite sides of the insertion bottom wall 20311 in the first direction X, and the insertion groove C1 is defined between the insertion bottom wall 20311 and the two insertion side walls 20312.

When the corresponding heat exchange unit 20 is in the second state, the corresponding heat exchange unit 20 is supported via the two insertion side walls 20312 (as shown in FIG. 4), and a risk of the heat exchange unit 20 from break under gravity of the heat exchange medium 80 is reduced.

In one embodiment, referring to FIG. 9, the memory module 201 further includes capacitance-type resistor 2014. The capacitance-type resistor 2014 is below the chip 2012. The main part 29 corresponds to the chip 2012 in the first direction X, and the main part 29 is above the capacitance-type resistor 2014. A possibility of the main part 29 being damaged by the capacitance-type resistor 2014 is reduced, and the service life of the heat dissipation device 100 is improved.

In one embodiment, referring to FIG. 9, the heating dissipation device 100 further includes a plurality of supporting portions 60. When the second heat exchange section 22 of the plurality of heat exchange units 20 is in the second state, the second hear exchange section 22 is supported by the plurality of supporting portions 60wa. Two supporting portions 60 are respectively located at two opposite sides of the card connector 203. A height of the supporting portion 60 is higher than a height of the insertion portion 2031, and a height of the supporting portion 60 is lower than a height of the chip 2012. The main part 29 or the second heat exchange section 22 of the heat exchange unit 20 is supported by the plurality of supporting portions 60. The supporting portion 60 provides stable support to the heat exchange section 29, and the supporting portion 60 prevents the heat exchange section 29 from falling to a side of the capacitance-type resistor 2014.

In one embodiment, referring to FIG. 9, When the heat exchange unit 20 is switched from the first state to the second state, a dimension of the first side wall 25 in the third direction Z is increased to correspond to a heat-generating area of the heat source member 201. A dimension of the second side wall 27 in the third direction Z is increased to correspond to another heat-generating area of the heat source member 201. The heat-generating area of the heat source member 201 is the chip 2012.

The dimension of the first side wall 25 in the third direction Z is increased to cover the dimension of the chip 2012 in the third direction Z. The dimension of the second side wall 27 along the third direction Z is increased to cover the dimension of the chip 2012 along the third direction Z. A contact area between the chip 2012 and the heat exchange unit 20 is ensured.

In one embodiment, the heat exchange unit 20 is a pipe structure formed by a single silicone layer. In another embodiment, tube wall of the heat exchange unit 20 is made of a plurality of functional film layers. The plurality of functional film layers includes anti-permeability layer, strength layer and heat conduction layer. A strength, a permeability resistance and a thermal conductivity of the heat exchange unit 20 is improved.

In one embodiment, the memory module 201 includes a plurality of chips 2012 with different heights. Since the heat exchange unit 20 is formed by a single silicone layer, and the heat exchange unit 20 has flexibility. The first side wall 25 and the second side wall 27 of the heat exchange unit 20 in the second state can squeeze and absorb heat with the plurality of chips 2012 with different heights.

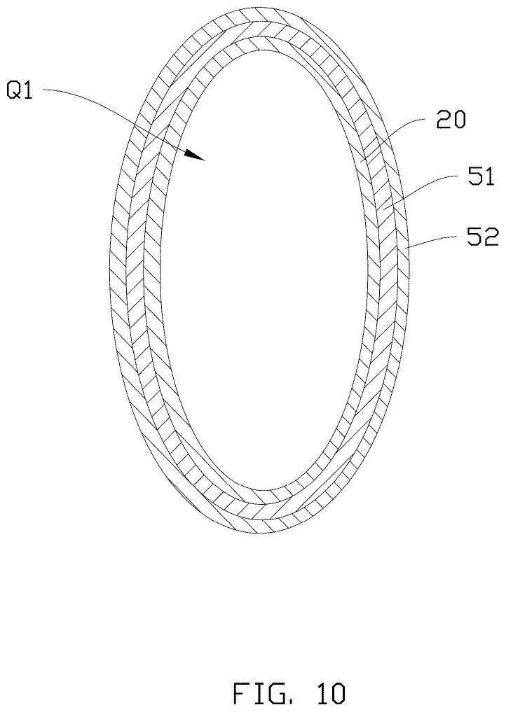

In one embodiment, referring to FIG. 10, the heating dissipation device 100 further includes a thermal interface layer 51 and a protection layer 52. The thermal interface layer 51 is wrapped around the heat exchange unit 20 and is between the hear exchange unit 20 and the protective layer 52. The protective layer 52 is on the thermal interface layer 51. The thermal interface layer 51 may be made of flexible thermal conductive materials such as heat sink gasket, thermal glue, silicone grease. This improving heat exchange performance and deformation property of the heat exchange unit 20, making it easy for the heat exchange unit 20 to deform, and improving a contact area between the heat exchange 20 and the chip 2012, further improving heat exchange performance. The protection layer 52 may be made of flexible thermal conductive materials such as polyimide film, the polyimide film combines flexibility, heat exchange performance and wear resistance. A friction loss of contact between the heat exchange unit 20 and the memory module 201 is reduced, and a risk of leakage of the heat exchange unit 20 is reduced, and the service life of the heat exchange unit 20 is improved.

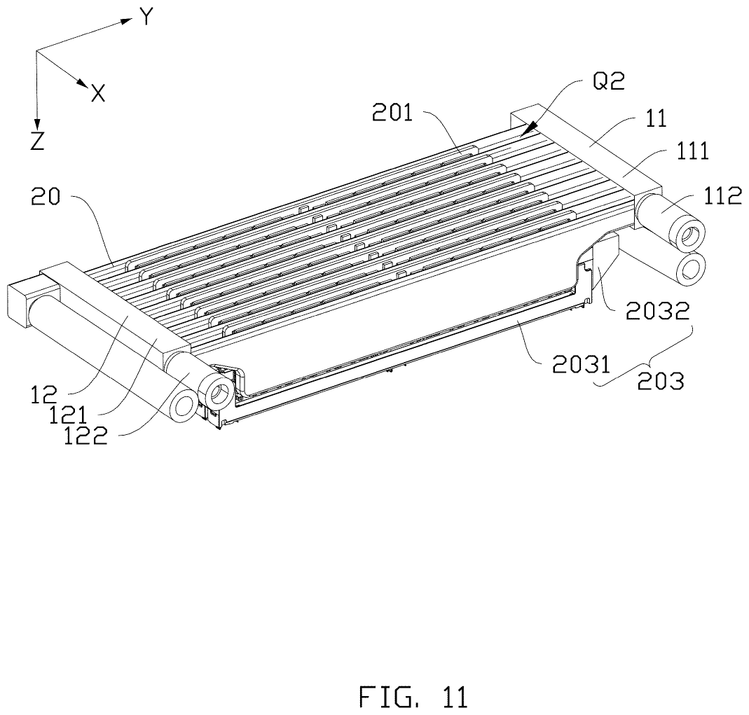

FIG. 11 shows another embodiment of the heating dissipation device 100, in this embodiment, the heat dissipation device 100 includes a first medium transmission member 11 and a second medium transmission member 12. The first medium transmission member 11 and the second medium transmission member 12 are spaced apart along the first direction X. The heat exchange member 30 is connected between the first medium transmission member 11 and the second medium transmission member 12. The heat exchange unit 20 is connected between the first medium transmission member 11 and the second medium transmission member 12. This allows the first medium transmission member 11 and the second medium transmission member 12 to simultaneously absorb heat from the heat exchange member 30, and a heat exchange efficiency of the heat source member 201 is further improved.

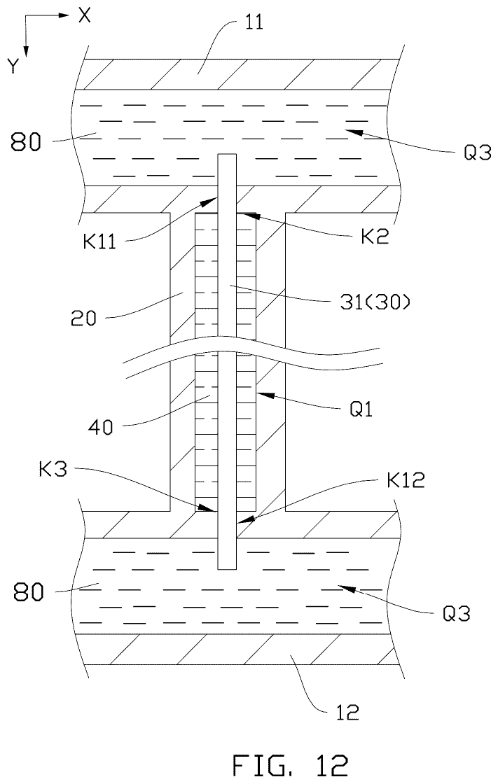

In one embodiment, referring to FIG. 12, the first medium transmission member 11 has a plurality of first communicating holes K11. The second medium transmission member 12 has a plurality of second communicating holes K12. Each of the plurality of first ends 33 is respectively extended into a corresponding the first communicating communication hole K11. Each of the plurality of second ends 34 is respectively extended into a corresponding the second communicating communication hole K12. An installation stability of the heat exchange member 30 is improved.

In one embodiment, the heat exchange medium 80 is imported into the first medium transmission member 11. The heat exchange medium 80 is exported from the second medium transmission member 12. The heat dissipation device 100 further includes a liquid cooling plate 73, a first transmission tube 71 and a second transmission tube 72. The liquid cooling plate 73 is connected between the first transmission tube 71 and the second transmission tube 72. The first transmission tube 71 is connected with the first medium transmission member 11, and the second transmission tube 72 is connected with the second medium transmission member 12. The heat is absorbed to the heat exchange medium 80 in the first transmission tube 71 via the heat exchange unit 20 and the heat exchange member 30, the liquid cooling plate 73 absorbed heat from the heat exchange medium 80, and the cooled heat exchange medium 80 is exported to the second transmission tube 72, this realizing cyclic heat exchange of the heat exchange medium 80, improving heat exchange efficiency, and integration of the heat dissipation device 100.

In one embodiment, referring to FIG. 11, the first medium transmission member 11 includes a first delivery pipe 111 and a first delivery connector 112. The first delivery connector 112 is connected with an end of the first delivery pipe 111. The first delivery pipe 111 is connected with the first transmission tube 71. One of the two first connection parts 28 is connected with a side surface of the first delivery pipe 111. The second medium transmission member 12 includes a second delivery pipe 121 and a second delivery connector 122. The second delivery connector 122 is connected to an end of the second delivery pipe 121. The second delivery pipe 122 is connected to the second transmission tube 72. Another one of the two first connection parts 28 is connected to a side surface of the second delivery pipe 121.

In other embodiment, the heat exchange medium 80 is transported between the first medium transmission member 11 and the second medium transmission member 12, and the heat exchange medium 80 with low temperature absorbs heat from the heat exchange member 30.

In one embodiment, referring to FIG. 12, each of the plurality of heat exchange units 20 includes a medium outlet K3 and a medium inlet K2. The medium outlet K3 and the medium inlet K2 are spaced apart in respective ends of the corresponding heat exchange unit 20 in the second direction Y. The medium outlet K3 of a heat exchange unit 20 of the plurality of heat exchange units 20 is serially connected the medium outlet K3 of an adjacent heat exchange unit 20 of the plurality of heat exchange units 20. The medium inlet K2 of the heat exchange unit 20 is serially connected the medium inlet K2 of the adjacent heat exchange unit 20. A first heat exchange unit 20 of the plurality of heat exchange units 20 is connected to the first medium transmission member 11, and a last heat exchange unit 20 of the plurality of heat exchange units 20 is connected to the second medium transmission member 12. Then heat exchange medium 80 is exported from the second medium transmission member 12.

In one embodiment, referring to FIG. 11, a length direction of the medium transmission member 10 is parallel to the first direction X, and multiple heat exchange units 20 are spaced apart at intervals along the first direction X. The plurality heat exchange cavities Q1 are connected in parallel to the transmission cavity Q3.

In other embodiments, the plurality heat exchange units 20 can also be connected to the first medium transmission member 11 and the second medium transmission member 12 in both parallel and series connections.

In one embodiment, the heat exchange unit 20 and the medium transmission member 10 is an integral structure, and the heat exchange unit 20 is made by a deformable material. The heat exchange unit 20 can maintain deformation ability after multiple deformations, and the service life of the heat exchange unit 20 is improved. A problem of heat exchange medium 80 leakage caused by tube alignment is reduced. The heat exchange unit 20 and the medium transmission member 10 can be formed via molding methods such as over molding or two-shot injection molding. The material of the medium transmission member 10 may be copper, stainless steel, plastic, rubber tube, EPDM, Teflon tube, etc.

In one embodiment, the heat exchange unit 20 and the medium transmission member 10 can be bonded with an adhesive, such as UV glue.

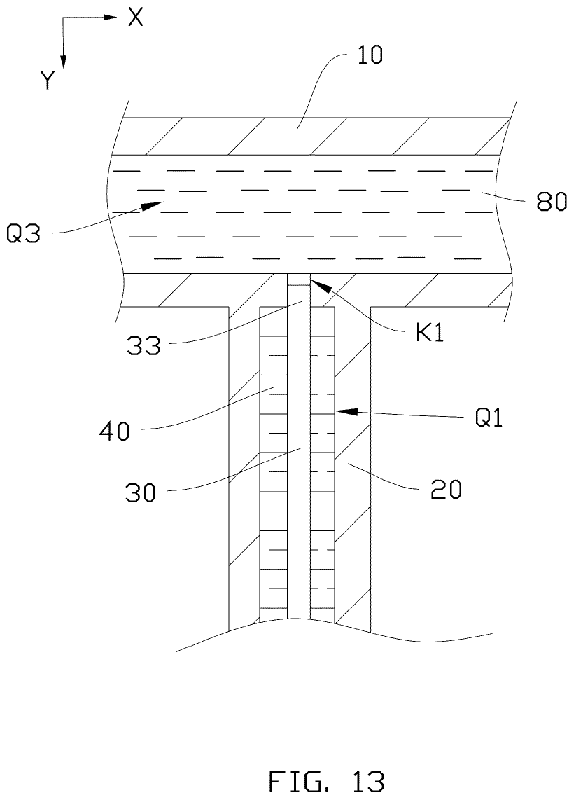

FIG. 13 shows another embodiment of the heating dissipation device 100, in this embodiment, the first end 33 is received in the communication hole K1, the containment cavity Q3 is connected with the communication hole K1, and an end face of the first end 33 absorb heat with the heat exchange medium 80. A possibility of collision and damage between the heat exchange member 30 and the medium transmission member 10 is reduced, the service life of the medium transmission member 10 is increased.

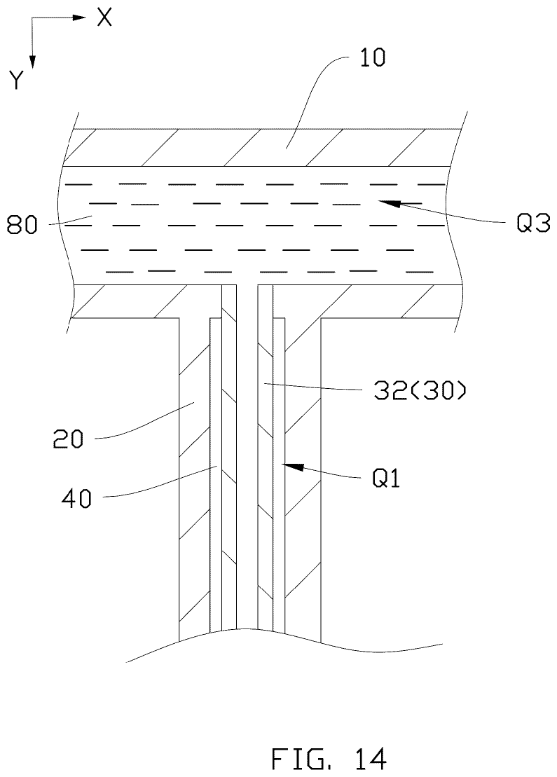

FIG. 14 shows another embodiment of the heating dissipation device 100. In this embodiment, the heat exchange member 30 is a heat pipe 32 communicating with the transmission cavity Q3 and configured to receive the heat exchange medium 80. This allowing the heat exchange medium 80 flow into the heat pipe 32 and then absorb heat with the heat source member 201 via the phase change medium 40.

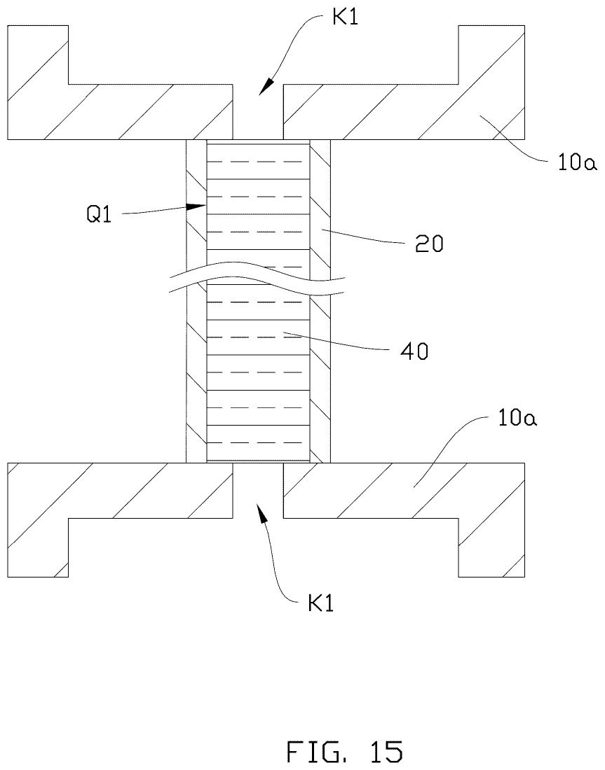

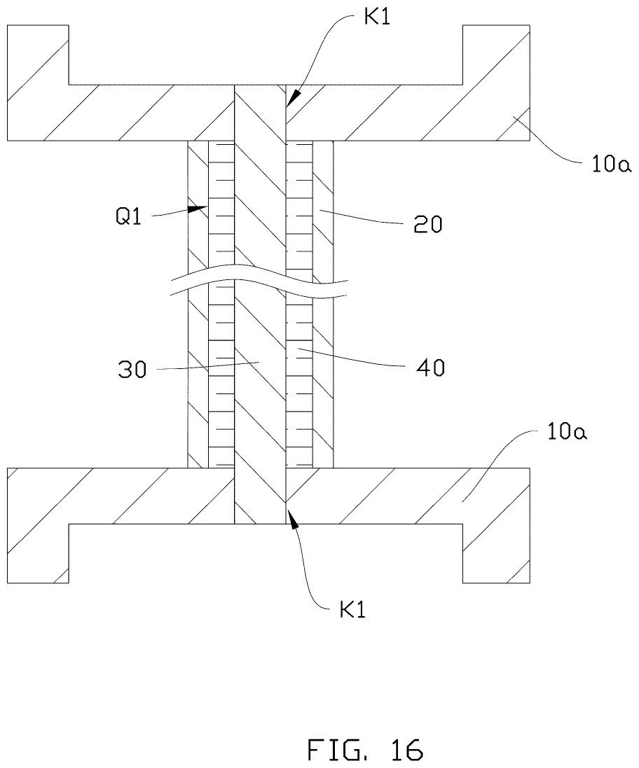

Referring to FIG. 15-17, an embodiment of the present disclosure provides a manufacturing method for a heat dissipation device 100, the manufacturing method includes:
At least one medium transmission member 10 with a communication hole K1 in a side wall of the medium transmission member 10 is provided;
A plurality of heat exchange units 20 is provides, and the plurality of heat exchange units 20 is connected to an outer surface of the medium transmission member 10, and the heat exchange cavity Q1 of each of the plurality of heat exchange units 20 is connected to the communication hole K1 of the medium transmission member 10;
A heat exchange member 30 is provided to each of the plurality of hear exchange units 20. The heat exchange member 30 is inserted into the heat exchange cavity Q3 through the communication hole K1. One end of the heat exchange member 30 is received in the communication hole K1. The communication hole K1 is sealed, and the heat exchange member 30 is connected to the medium transmission member 10;
A heat exchange medium 40 is provided. The heat exchange medium 40 is filled into the heat exchange cavity Q1. A temperature of the heat exchange medium 40 is increased such that the heat exchange medium 40 is in a liquid state. A shape of each of the plurality of heat exchange units 20 when the heat exchange medium 40 is in the liquid state thereby obtaining a shape of each of the plurality of heat exchange units 20 in the first state; and the temperature of the heat exchange medium 40 is decreased such that the heat exchange medium 40 is in a solidify state, and maintaining the shape of each of the plurality of heat exchange units 20 in the first state.

The step of the heat exchange member 30 is connected to the medium transmission member 10 includes:
Two opposite ends of the heat exchange unit 20 is connected between the first medium transmission member 11 and the second medium transmission member 12. A heat exchange medium 40 is injected into the heat exchange cavity Q1 through the first communication hole K11;
A heat exchange member 30 is inserted into the heat exchange cavity Q1. A first end 33 of the heat exchange member 30 is received in the first communication hole K11. The first end 33 is connected to the first medium transmission member 11. The second end 34 of the heat exchange member 30 is received in the second communication hole K12, and the second end 34 is connected to the second medium transmission member 12.

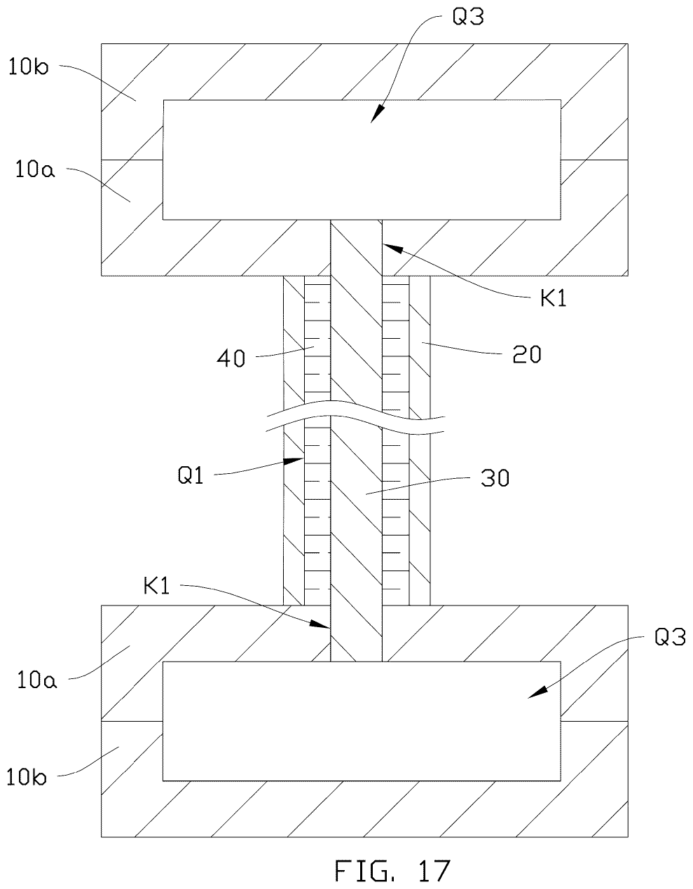

In one embodiment, referring to FIG. 17, the medium transmission member 10 includes a first member 10a and a second member 10b. The first member 10a and the second member 10b are U-shaped structures with opposite openings The first member 10a and the second member 10b are connected to each other to form the sealed transmission cavity Q3. During assembly processing of the medium transmission member 10, the heat exchange unit 20 and the heat exchange member 30, the heat exchange member 30 and the heat exchange unit 20 are installed in a groove of the first member 10a, and the phase change medium 40 is transported into the heat exchange cavity Q1 via the groove of the first member 10a, then the second member 10b is connected to the first member 10a A manufacturing efficiency of the heating dissipation device 100 is improved. In other embodiments, the medium transmission member 10 can also be made as a whole molding structure.

The above embodiments are only used to illustrate the technical solutions of the present application rather than limitations. Although the present application has been described in detail with reference to the above preferred embodiments, one of ordinary skill in the art should understand that the technical solutions of the present application may be modified or equivalently replaced without departing from the spirit and scope of the technical solutions of the present application.

What is claimed is:

1. A heating dissipation device comprising:
at least one medium transmission member each comprising a transmission cavity configured for conveying a heat exchange medium;
a plurality of heat exchange units spaced apart from each other and connected to the medium transmission member, wherein a receiving space is defined between each two adjacent heat exchange units of the plurality of heat exchange units, the receiving space receives a heat source member, each of the plurality of heat exchange units further comprising a heat exchange cavity;
a heat exchange member arranged in the heat exchange cavity, and configured to absorb heat generated from the heat source member and transfer the heat to the transmission member,
wherein each of the plurality of heat exchange units is configured to be in a first state or in a second state, wherein when a heat exchange unit of the plurality of heat exchange units is in the first state, adjacent heat exchange units of the plurality of heat exchange units are spaced apart from the heat source member, and a size of the receiving space is slightly larger than a size of the heat source member; and when the heat exchange unit is in the second state, the heat exchange unit is expanded, and the adjacent heat exchange units are close to each other to clamp the heat source member.

2. The heat dissipation device of claim 1, wherein each of the plurality of heat exchange units further comprising a first side wall and a second side wall opposite to the first wall, and each of the plurality of heat exchange units is configured to accommodate a phase change medium between the heat exchange member and an inner surface of a corresponding heat exchange unit of the plurality of heat exchange units, wherein
the corresponding heat exchange unit is further configured to be in the first state when a temperature of the phase change medium is below a preset value; and
the corresponding heat exchange unit is further configured to switch to the second state when the temperature of the phase change medium is equal to or above the preset value, wherein the corresponding heat exchange unit is expanded by expanding the first side wall and the second side wall by a distance, by the phase change medium, such that at least one of the first side wall and the second side wall clamps the heat source member, thereby forming a heat transfer path from the heat source member to the corresponding heat exchange unit, to the phase change medium, to the heat exchange member, and to the heat exchange medium.

3. The heat dissipation device of claim 2, wherein the medium transmission member further comprises a connection side wall, the connection side wall comprises a communication hole communicating with the transmission cavity; one end of the heat exchange member extends into the communication hole and is connected to the medium transmission member.

4. The heat dissipation device of claim 3, wherein the end of the heat exchange member is sealed with the medium transmission member, the heat exchange cavity is isolated from the transmission cavity.

5. The heat dissipation device of claim 2, wherein each of the plurality of heat exchange units comprises a first heat exchange section and a second heat exchange section, the first heat exchange section is connected to the medium transmission member, the heat exchange member is received in the first heat exchange section of the corresponding heat exchange unit, and a gap is defined between the heat exchange member and an inner surface of the first heat exchange section of the corresponding heat exchange unit, the second heat exchange section is connected to a downside in a gravity direction of the first heat exchange section of the corresponding heat exchange unit.

6. The heat dissipation device of claim 1, wherein the at least one medium transmission members comprises a first medium transmission member and a second medium transmission member spaced apart from the first medium transmission member in first direction, and the heat exchange member is connected between the first medium transmission member and the second medium transmission member, and the plurality of heat exchange units is connected between the first medium transmission member and the second medium transmission member.

7. The heat dissipation device of claim 6, further comprising a liquid cooling plate; a first transmission tube; and a second transmission tube, wherein the liquid cooling plate is connected between the first transmission tube and the second transmission tube, the first transmission tube is connected with the first medium transmission member, the second transmission tube is connected with the second medium transmission member.

8. The heat dissipation device of claim 6, wherein each of the plurality of heat exchange units further comprises a medium outlet and a medium inlet, the medium outlet and the medium inlet are spaced apart in respective ends of the corresponding heat exchange unit; the medium outlet of a heat exchange unit of the plurality of heat exchange units is serially connected the medium outlet of an adjacent heat exchange unit of the plurality of heat exchange units, and the medium inlet of the heat exchange unit is serially connected the medium inlet of the adjacent heat exchange unit; a first heat exchange unit of the plurality of heat exchange units is connected to the first medium transmission member, and a last heat exchange unit of the plurality of heat exchange units is connected to the second medium transmission member.

9. The heat dissipation device of claim 1, wherein the at least one medium transmission member and the plurality of heat exchange units is an integral structure, the plurality of heat exchange units is made by a deformable material.

10. The heat dissipation device of claim 1, wherein the at least one medium transmission member each further comprising a connection side wall having a communication hole, the communication hole communicates with the transmission cavity, an end of the heat exchange member is extended into the communication hole.

11. The heat dissipation device of claim 10, wherein the end of the heat exchange member is further extended into the transmission cavity.

12. The heat dissipation device of claim 1, wherein the heat exchange member is a heat pipe communicating with the transmission cavity and configured to receive the heat exchange medium.

13. The heat dissipation device of claim 1, wherein the heat exchange unit comprises a first heat exchange section and a second heat exchange section; the first heat exchange section is connected to the medium transmission member, and the heat exchange member is received in the first heat exchange section, and a gap is defined between the heat exchange member and an inner surface of the first heat exchange section.

14. The electronic equipment of claim 13, wherein the heat dissipation device further comprises a plurality of supporting portions, when the second heat exchange section of the plurality of heat exchange units is in the second state, the second hear exchange section is supported by the plurality of supporting portions.

15. The heat dissipation device of claim 1, further comprising a thermal interface layer and a protection layer; the thermal interface layer is wrapped around the heat exchange unit and is between the hear exchange unit and the protective layer, the protective layer is on the thermal interface layer.

16. A manufacturing method of the heat dissipation device of claim 1, the manufacturing method of heat dissipation device comprising:
providing the at least one medium transmission member having a communication hole in a side wall of the medium transmission member;
providing the plurality of heat exchange units, connecting the plurality of heat exchange units on an outer surface of the medium transmission member, and connecting the heat exchange cavity of each of the plurality of heat exchange units and the communication hole of the medium transmission member;
providing the heat exchange member to each of the plurality of hear exchange units, inserting the heat exchange member into the heat exchange cavity through the communication hole, connecting one end of the heat exchange member to the communication hole of the medium transmission member and sealing the communication hole thereby connecting the heat exchange member to the medium transmission member;
providing the heat exchange medium, filling the heat exchange medium into the heat exchange cavity, increasing a temperature of the heat exchange medium such that the heat exchange medium is in a liquid state, adjusting a shape of each of the plurality of heat exchange units when the heat exchange medium is in the liquid state thereby obtaining a shape of each of the plurality of heat exchange units in the first state; decreasing the temperature of the heat exchange medium such that the heat exchange medium is in a solidify state, and maintaining the shape of each of the plurality of heat exchange units in the first state.

17. The heat dissipation device of claim 16, wherein a quantity of the at least one medium transmission member provided is two medium transmission members comprising a first medium transmission member and a second medium transmission member, a first communication hole is defined in a side wall of the first medium transmission member, a second communication hole is defined in a side wall of the second medium transmission member;
connecting the heat exchange member to the medium transmission member comprises:
connecting two opposite ends of the plurality of heat exchange units respectively to the first medium transmission member and the second medium transmission member, injecting a phase change medium into the heat exchange cavity through the first communication hole;
inserting the heat exchange member into the heat exchange cavity, connecting a first end of the heat exchange member in the first communication hole, and connecting the first end of the heat exchange member to the first medium transmission member;
connecting a second end of the heat exchange member in the second communication hole, and connecting the second end of the heat exchange member to the second medium transmission member.

18. An electronic equipment comprising:
a heating dissipation device comprising:
at least one medium transmission member each comprising a transmission cavity configured for conveying a heat exchange medium;
a plurality of heat exchange units spaced apart from each other and connected to the medium transmission member, wherein a receiving space is defined between each two adjacent heat exchange units of the plurality of heat exchange units, the receiving space receives a heat source member, each of the plurality of heat exchange units further comprising a heat exchange cavity;
a heat exchange member arranged in the heat exchange cavity, and configured to absorb heat generated from the heat source member and transfer the heat to the transmission member,
wherein each of the plurality of heat exchange units is configured to be in a first state or in a second state, wherein when a heat exchange unit of the plurality of heat exchange units is in the first state, adjacent heat exchange units of the plurality of heat exchange units are spaced apart from the heat source member, and a size of the receiving space is slightly larger than a size of the heat source member; and when the heat exchange unit is in the second state, the heat exchange unit is expanded, and the adjacent heat exchange units are close to each other to clamp the heat source member; and
a heat source member received in the receiving space.

19. The electronic equipment of claim 18, further comprising a card connector; and a circuit board, wherein the card connector is arranged on the circuit board, the card connector comprises an insertion portion comprising an insertion bottom wall and two insertion side walls, the two insertion side walls are respectively connected to two sides of the insertion bottom wall, and an insertion groove is defined between the insertion bottom wall and the two insertion side walls; when the corresponding heat exchange unit is in the second state, the two insertion side walls supported the corresponding heat exchange unit.

20. The electronic equipment of claim 19, wherein the card connector further comprises two locking portions, the two locking parts are respectively connected to two opposite sides of the insertion portion;
each of the plurality of heat exchange units further comprises a connection part and a main part; the connection part is connected to one end of the heat exchange part, and the main part corresponds to the insertion portion, the connection part corresponds to one of the two locking portions.
